(19) United States
(12) Patent Application Publication
(10) Pub. No.: US 2026/0101555 A1
(43) Pub. Date: Apr. 9, 2026

(54) LATTICE-MATCHED HETEROSTRUCTURE DEVICE

(71) Applicant: Cornell University, Ithaca, NY (US)

(72) Inventors: Len van Deurzen, Ithaca, NY (US); Thai-Son Nguyen, Ithaca, NY (US); Joseph Casamento, State College, PA (US); Huili Grace Xing, Ithaca, NY (US); Debdeep Jena; Chandrashekhar Prakash Savant, Ithaca, NY (US)

(21) Appl. No.: 18/900,573

(22) Filed: Sep. 27, 2024

Related U.S. Application Data
(60) Provisional application No. 63/540,746, filed on Sep. 27, 2023.

(51) Int. Cl. H10D 62/815; H01S 5/343; H10D 30/47; H10H 20/812; H10H 20/822

(52) U.S. Cl. CPC H10D 62/8164; H01S 5/34393; H10D 30/474; H10D 30/475; H10H 20/812; H10H 20/822

(57) ABSTRACT

A heterostructure includes a substrate and a layer stack of layer pairs on the substrate. The heterostructure may be part of a field-effect transistor or light emitting device, such as a laser, an LED, or a quantum cascade emitter. Each of the layer pairs includes (i) a first nitride layer that includes a metal and (ii) a second nitride layer that includes aluminum and gallium. A material composition of the first nitride layer may be Al₁₋ₓMₓN, where x is between 0.01 and 0.18, inclusive, and M includes one or more of a group-III element, a rare earth element, boron, and gallium. A material composition of the second nitride layer may be Al_{1-y}Ga_{y}N, where y is between 0.85 and 1.0, inclusive.

### CROSS-REFERENCE TO RELATED APPLICATIONS

This application claims the benefit of U.S. Provisional Application No. 63/540,746, filed on Sep. 27, 2023, the disclosure of which is incorporated herein by reference in its entirety.

### STATEMENT REGARDING FEDERALLY SPONSORED RESEARCH

This invention was made with government support under Grant No. DMR-1719875 awarded by the National Science Foundation and Grant No. W911NF2220177 awarded by the Army Research Office. The government has certain rights in the invention.

### BACKGROUND

In recent years, the ultra-wide bandgap material [symbol] has emerged as a subject of intense research interest, particularly within the domain of semiconductor electronics and photonics. The intentional introduction of scandium into AlN has been found to result in a remarkable enhancement of its piezoelectric coefficients and, notably, the emergence of ferroelectricity.

### SUMMARY OF THE EMBODIMENTS

Embodiments disclosed herein include epitaxial lattice-matched [symbol] ten and twenty period distributed Bragg reflectors (DBRs) grown on c-plane bulk n-type GaN substrates by plasma-enhanced molecular beam epitaxy (PA-MBE). Resulting from a rapid increase of in-plane lattice coefficient as scandium is incorporated into AlScN, we measure a lattice-matched condition to c-plane GaN for a Sc content of just 11%, resulting in a large refractive index mismatch Δn greater than 0.3 corresponding to an index contrast of Δn/n_{GaN}=0.12 with GaN. Embodiments of DBRs disclosed herein are designed for a peak reflectivity at a wavelength of 400 nm reach a reflectivity of 0.98 for twenty periods. It is highlighted that AlScN/GaN multilayers require fewer periods for a desired reflectivity than other lattice-matched Bragg reflectors such as those based on AlInN/GaN multilayers. These advantages encourage the integration of transition metal nitrides with the existing III/N optoelectronic ecosystem. Such multilayer and superlattice structures are also of high interest for multichannel electronic device applications and for intersubband devices such as quantum cascade lasers.

In a first aspect, a heterostructure includes a substrate and a layer stack of layer pairs on the substrate. The heterostructure may be part of a field-effect transistor or light emitting device, such as a laser, an LED, or a quantum cascade emitter. Each of the layer pairs includes (i) a first nitride layer that includes a metal and (ii) a second nitride layer that includes aluminum and gallium. A material composition of the first nitride layer may be Al₁₋ₓMₓN, where x is between 0.01 and 0.18, inclusive, and M includes one or more of a group-III element, a rare earth element, boron, and gallium. A material composition of the second nitride layer may be Al_{1-y}Ga_{y}N, where y is between 0.85 and 1.0, inclusive.

### BRIEF DESCRIPTION OF THE FIGURES

FIG. 1. is a schematic cross-sectional view of a typical AlScN film grown on a bulk n^{+¿GaN¿} substrate for lattice parameters and refractive index dispersion characterizations.

FIG. 2 is a graph of a symmetric [symbol] X-ray diffraction (XRD) scan of thin Al_{0.89}Sc_{0.11} on bulk n-type GaN.

FIG. 3 depicts 2×2 μm² AFM micrograph showing clear atomic steps with rms=0.22 nm.

FIG. 4 is a graph of AlScN in-plane lattice parameter as a function of Sc composition measured from reciprocal space mapping of the AlScN (1015) peak.

FIG. 5 is a graph of the ordinary refractive index as a function of vacuum wavelength for Al₁₋ₓScₓN films of various Sc content, as well as GaN.

FIG. 6 is a schematic cross-sectional view of an embodiment of a ten period Al_{0.89}Sc_{0.11}N/GaN distributed Bragg reflector on bulk n^{+¿GaN¿}.

FIG. 7 depicts an AFM micrograph of the DBR of FIG. 6 with clear atomic steps (rms=0.34 nm) and streaky RHEED evolution of AlScN layers along the <110> zone axis.

FIG. 8 is a graph of a symmetric [symbol] scan shows a strong AlScN (0002) peak of the DBR of FIG. 6.

FIG. 9 is a XRD reciprocal space map of (101̅5) reflections which confirms that the AlScN and GaN layers of the DBR of FIG. 6 are pseudomorphically grown on the bulk n^{+¿GaN¿} substrate.

FIG. 10 shows measured (spectrophotometry) and simulated (TMM) reflectivity spectra of an embodiment of ten period (top) and twenty period (bottom) [symbol] distributed Bragg reflector.

FIG. 11 is a benchmark plot of embodiments of epitaxial lattice-matched nitride based distributed Bragg reflectors on GaN showing peak reflectivity vs. number of periods in the multilayer.

FIG. 12 is a cross-sectional schematic of a lattice-matched heterostructure, in an embodiment.

FIG. 13 is a cross-sectional schematic of a light emitting device that includes a lattice-matched heterostructure of FIG. 12, in an embodiment.

FIG. 14 is a cross-sectional schematic of a resonant cavity light-emitting diodes (RCLED) that includes a lattice-matched heterostructure of FIG. 12, in an embodiment.

FIG. 15 is a cross-sectional schematic of a vertical cavity surface-emitting laser (VCSEL) that includes a lattice-matched heterostructure of FIG. 12, in an embodiment.

FIG. 16 is a cross-sectional schematic of a quantum cascade emitter that includes a lattice-matched heterostructure of FIG. 12, in an embodiment.

FIG. 17 is a cross-sectional schematic of an embodiment of the lattice-matched heterostructure of FIG. 12.

FIG. 18 is a plan view of a multichannel field-effect transistor (FET) that includes lattice-matched heterostructure of FIG. 17.

FIG. 19 is a cross-sectional view of a multichannel field-effect transistor, which is an example of the FET of FIG. 18.

FIG. 20 is a plot of total electron density in two-dimensional electron gas layer of an embodiment of the heterostructure of FIG. 17.

FIG. 21 and FIG. 22 are plots of voltage-current characteristics of an embodiment of the FET of FIG. 18.

### DETAILED DESCRIPTION OF THE EMBODIMENTS

While significant efforts have been dedicated to study piezoelectricity and ferroelectricity of AlScN for integration in RF and memory applications, reports on optoelectronic applications of AlScN remain scarce. In spite of this, the existing properties that make AlScN an attractive material for GaN-based electronics could also make it a promising material for optoelectronic integration. For example, lattice-matched AlScN is a good barrier for GaN high-electron mobility transistors (HEMTs) to overcome the critical thickness limitation in (Al,Ga)N/GaN HEMTs. Similarly, lattice-matched AlScN can be competitive to replace or outperform AlN, AlGaN, and AlInN in optoelectronic applications where minimizing crystal degradation and crack formation are of high interest.

One particular example is in GaN-based distributed Bragg reflectors (DBRs) for nitride-based microcavities and vertical-cavity surface-emitting lasers (VCSELs) and resonant cavity light-emitting diodes (RCLEDs). AlN/GaN and AlGaN/GaN are the first semiconductor-based epitaxial DBRs explored for GaN-based VCSELs. Unlike dielectric DBRs (e.g. [symbol] -based), Al(Ga)N-based epitaxial DBRs do not require complex fabrication techniques like lift-off and bonding. However, growing thick, high-quality Al(Ga)N/GaN DBRs remains challenging and requires complex strain engineering schemes due to the large lattice mismatch between AlN and GaN. Low refractive index porous GaN can also induce a significant refractive index mismatch for GaN-based DBRs, but is limited by its complicated etching process and its potential for degrading structural integrity.

Lattice-matched [symbol] s a promising alternative to circumvent degradation of crystal and optical properties due to strain relaxation induced by lattice mismatch. However, the synthesis of high-quality AlInN thin films and AlInN/GaN layers is difficult because of the large difference in optimal growth temperatures for InN and AlN.

Furthermore, the refractive index mismatch Δn≈0.2 between [symbol] and GaN is quite low (relative contrast Δn/n_{GaN}≈0.08), meaning that more AlInN/GaN pairs are needed to achieve the same reflectivity demonstrated by Al(Ga)N/GaN DBRs. Lastly, GaN-based DBRs are often epitaxially integrated as the bottom reflector in photonic devices, so a high crystal quality is critical to achieving any further epitaxial integration of active layers.

In embodiments, replacement of AlInN with AlScN lattice-matched to GaN address these limitations since AlScN growth conditions are more compatible with GaN, and the lattice-matched condition occurs at a higher Al composition, which yields a higher index mismatch with GaN. To this end, it is essential to determine the AlScN/GaN lattice-matched condition and the dependence of the refractive index on [symbol] alloy composition, x.

Herein, we describe the dispersion of the refractive index of thin films of [symbol] near its lattice-matched condition with GaN. By studying films of approximately 80-100 nm thickness grown on bulk c-plane metal-polar [symbol] by PA-MBE, we find that the lattice-matched condition occurs at a scandium content of x=0.11. At this composition, we infer a refractive index mismatch Δn of approximately 0.3 and index contrast Δn/n_{GaN}=0.12 with respect to GaN, throughout the UV-A, visible, and near-infrared (NIR) spectral regimes. With this significant index mismatch and low optical losses due to the ultra-wide bandgap of approximately 5.6 eV for [symbol] , high-reflectivity distributed Bragg reflectors are feasible for wavelengths limited by the bandgap of GaN (3.4 eV).

In comparison with AlInN/GaN Bragg reflectors, the higher index mismatch in AlScN/GaN near the lattice matched scandium composition predicts the need for fewer periods and, therefore, a lower total film thickness for a given desired peak reflectivity. Furthermore, we experimentally demonstrate such Bragg reflectors with peak reflectivity at a wavelength of 400 nm by growing ten-period and twenty-period multilayers, yielding a peak reflectivity of 0.98.

All AlScN films and multilayer structures in this work were grown on the c-plane of bulk silicon-doped Ga-polar n-type GaN [symbol] from Ammono. A Veeco GenXplor MBE reactor was used for all growths in this study. Scandium, aluminium, gallium, and silicon were provided using effusion K-cells. Active nitrogen species was provided using an RF plasma source with a 1.95 sccm nitrogen flowrate and 200 W RF power. The surface morphology was characterized by an Asylum Research Cypher ES atomic force microscope (AFM). A PANalytical Empyrean system with Cu K [symbol] radiation was used for X-ray diffraction (XRD), X-ray reflectivity (XRR) and reciprocal space mapping (RSM) to determine crystal structure, out-of-plane and in-plane lattice constants, and thin film thickness, respectively.

The scandium composition was measured by energy-dispersive X-ray spectroscopy using a Zeiss LEO 1550 FESEM equipped with a Bruker energy dispersive X-ray spectroscopy (EDS) silicon drift detector (SDD). The refractive index and optical loss dispersion for in-plane polarized light were measured with a Woollam RC2 spectroscopic ellipsometer using the single layers of AlScN grown on the bulk [symbol] substrates.

Reliable measurements were enabled by applying Mueller matrix ellipsometry in an optical window ranging from 193 nm to 1690 nm. Finally, the reflectivity spectra of the AlScN/GaN DBRs were then measured by using an Agilent Cary 5000 UV-Vis-NIR spectrophotometer. The spectra were calibrated by using a UV-enhanced Aluminum mirror with well-known reflectivity.

The AlScN films were grown under nitrogen-rich conditions to promote scandium incorporation and preserve the wurtzite phase purity. A metal (Sc+Al) to nitrogen (III/V) ratio of 0.7 was employed. GaN was grown under metal-rich conditions to promote the step-flow growth mode for high crystallinity. The growth rates for AlScN and GaN were 3.0 nm/min and 3.8 nm/min, respectively. All growths were monitored in situ by reflection high-energy electron diffraction (RHEED).

Thin films of AlScN were grown on bulk [symbol] substrates to determine the lattice-matched condition. For each sample, a 100 nm Si-doped [symbol] GaN layer was grown at a substrate temperature of 630 [symbol] measured by a thermocouple. Excess Ga was fully consumed before the N-rich AlScN growth, followed by 80-100 nm AlScN grown at 530 [symbol] thermocouple temperature. Note that the thermocouple substrate temperatures are approximately 50 [symbol] below the true temperature. Based on the measured ordinary refractive index and lattice matched composition, [symbol] and GaN quarter-wavelength thicknesses were calculated for a peak reflectivity targeted at a vacuum wavelength of 400 nm. After the growth of a 100 nm unintentionally doped (UID) GaN buffer layer at 530 [symbol] C, ten period and twenty period DBR structures were grown with the targeted quarter wavelength layer thicknesses.

GaN was grown at the optimal growth temperature of AlScN to prevent growth interruption between layers. The Ga flux was calibrated to achieve approximately 8 seconds of Ga droplets for a 10 minute GaN growth; excess Ga consumption was accounted for in the total growth time to control the GaN thickness precisely. Similar AlScN layer thicknesses were achieved by using the same III/V ratio (0.7) and growth time.

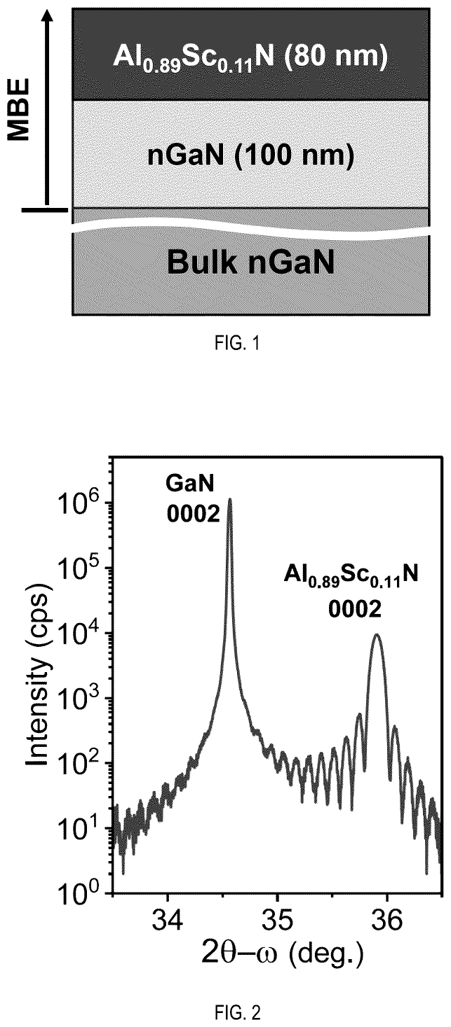

The thin (80-100 nm) AlScN films, as depicted in FIG. 1, are stabilized in the wurtzite phase, as confirmed by the strong (0002) AlScN diffraction peak near 2θ= [symbol] as shown in FIG. 2. FIG. 2 is a graph of a symmetric [symbol] X-ray diffraction (XRD) scan of thin Al_{0.89}Sc_{0.11} on bulk n-type GaN. For AlScN films with Sc composition around 12%, strong Pendellösung fringes are observed in the symmetric XRD scan, suggesting high interface quality between AlScN and [symbol] layers.

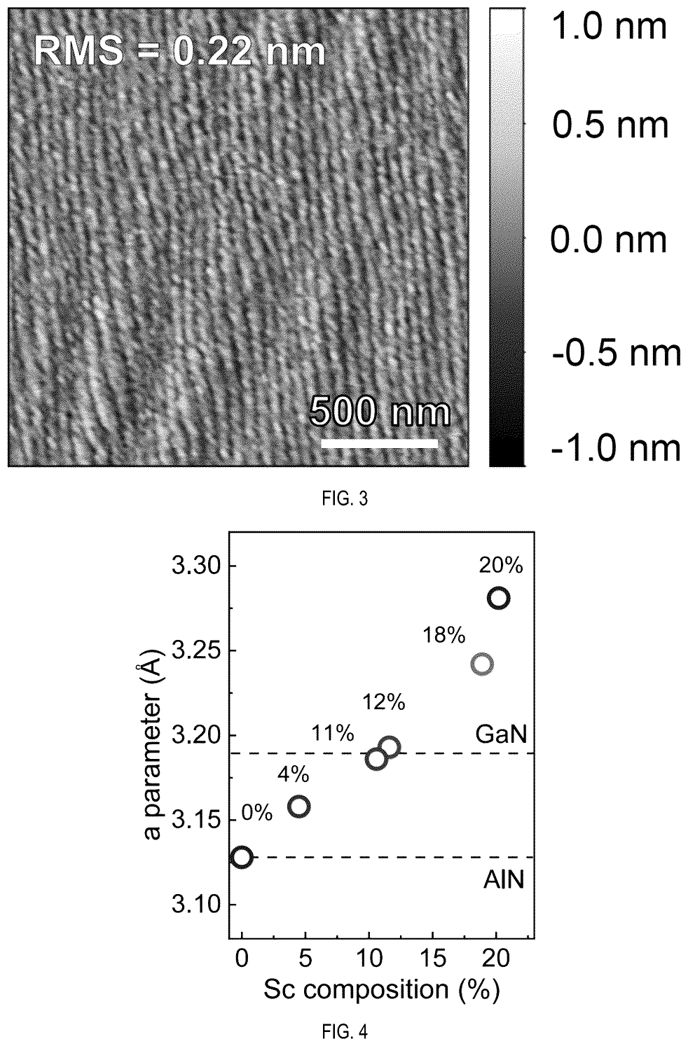

More importantly, when AlScN is nearly fully strained to the GaN substrate at a scandium incorporation of 11%, the two-dimensional step-flow growth mode and surface root-mean-square (rms) roughness below 3 Å could be achieved despite the nitrogen-rich growth condition, as shown in FIG. 3, which is a 2×2μm² AFM micrograph showing clear atomic steps with rms=0.22 nm.

FIG. 4 is a graph of AlScN in-plane lattice parameter as a function of Sc composition measured from reciprocal space mapping of the AlScN (101̅5) peak. FIG. 4 shows that, from in-plane lattice constants at different Sc content, the lattice-matched condition is determined to lie between 11% and 12% Sc.

These results suggest that nominally lattice-matched AlScN films of 80-100 nm thickness can be well integrated with GaN to achieve pseudomorphic AlScN/GaN multilayer structures which are highly crystalline and display sharp interfaces.

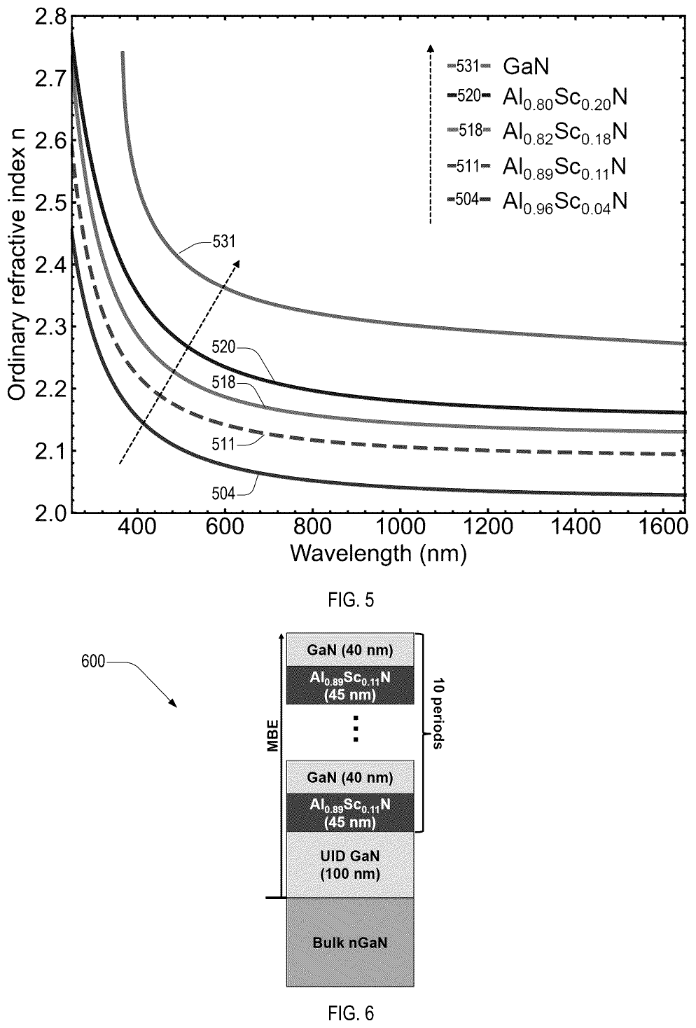

FIG. 5 shows the ordinary refractive index of AlScN as a function of Sc composition and wavelength determined from Mueller matrix ellipsometry measurements. FIG. 5 includes curves 504, 511, 518, 520, which correspond to different concentrations of Sc in AlScN. Dashed curve 511 corresponds to the nominally lattice-matched [symbol] sample.

The refractive index difference between [symbol] and GaN (curve 531) is Δn=0.3 (Δn/n_{GaN}=0.12) for a vacuum wavelength λ=400 nm; this is significantly larger than Δn≈0.2 (Δn/n_{GaN}=0.06-0.08) for lattice-matched AlInN/GaN. The larger index mismatch is enabled partly by AlScN having a larger lattice-matched aluminum composition than AlInN due to the rapid increase of in-plane lattice constant with Sc composition FIG. 4. It is important to note that various lattice-matched compositions between 9% and 18% Sc have been reported for AlScN grown by different methods and conditions. Therefore, the specific design parameters (refractive index, layer thickness, lattice matched condition) would vary depending on the growth conditions and specific structural and optical properties of AlScN films.

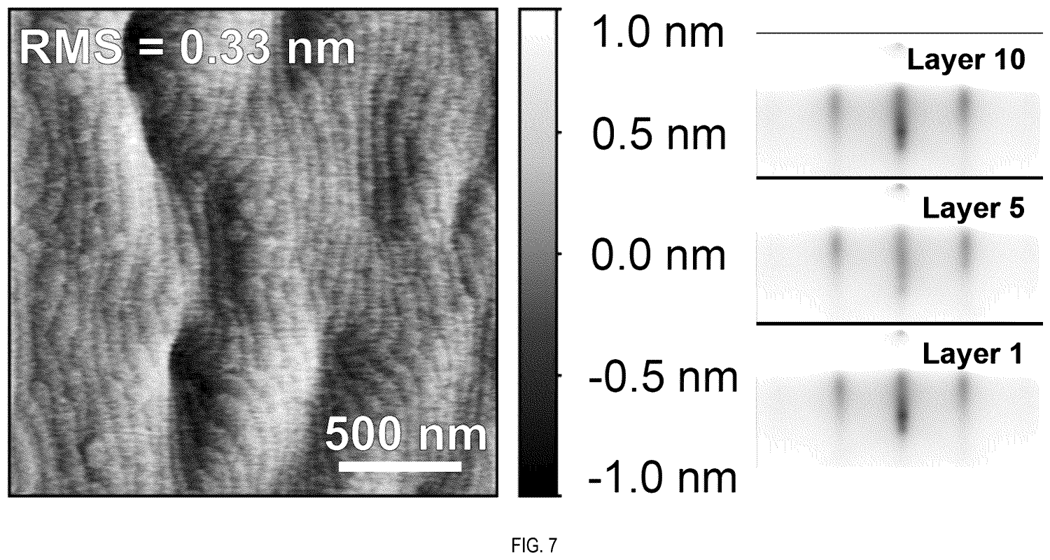

Accurate thickness control is also critical for a good DBR since the reflectivity depends strongly on the layer thicknesses. FIG. 6 shows a AlScN/GaN DBR multilayer structure 600 designed with intended thicknesses of 45 nm and 40 nm for [symbol] and GaN, respectively, for λ=400 nm (λ/4n for each layer). To precisely control layer thicknesses, the molecular beam fluxes and substrate temperature were kept constant throughout the growth. The substrate thermocouple temperature (530 [symbol] ) is lower than the optimal growth temperature of GaN but is optimal for AlScN and helps minimize the growth interruption between alternating AlScN and GaN layers. The growth conditions reported here are more easily controlled than in AlInN/GaN multilayer growths, which requires careful temperature and flux control due to high In desorption and InN decomposition rates at temperatures suitable for GaN and AlN growths. FIG. 7 shows a streaky RHEED pattern along the <110> zone axis in all AlScN layers grown under nitrogen-rich conditions. This is in accordance with the RHEED pattern and surface morphology in the nominally lattice-matched single-layer AlScN heterostructure FIG. 3 and in other studies.

Furthermore, the smooth surface morphology is maintained after ten FIG. 7 and even twenty [symbol] periods. Specifically, a root-mean-square surface roughness of 0.33 Å and clear atomic steps were achieved for a total growth thickness of 950 nm in the ten period DBR sample despite the nitrogen rich AlScN growth, highlighting the high crystallinity and interface qualities of nominally lattice-matched growth conditions.

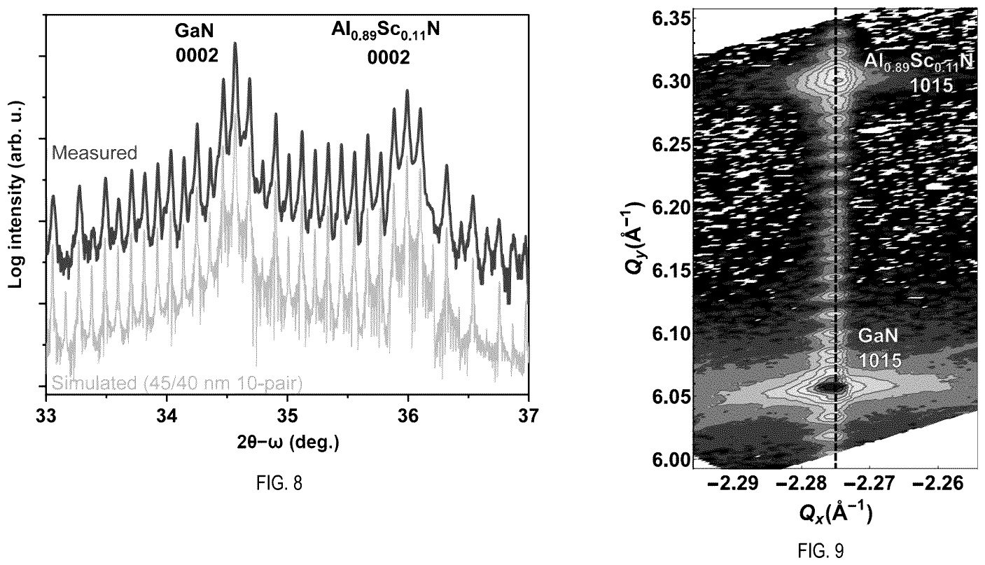

FIG. 8 further shows the high interface quality and precise thickness control achieved by using MBE. Sharp interfaces between AlScN and GaN layers are evidenced by the strong interference fringes in the 2θ-ω scans corresponding to the ten period FIG. 8 and twenty periods. The spacing between the interference fringes matches well with a simulated multilayer structure of 10-pairs of AlScN/GaN with thicknesses of 45/40 nm per pair. FIG. 9 shows AlScN (10\acute{1}5), GaN (10\acute{1}5) and all satellite peaks aligned vertically in the reciprocal space map, confirming that all multilayers are pseudomorphically grown on the bulk [symbol] substrate. This would enable higher crystal quality by minimizing dislocation generation due to strain relaxation.

Due to growth-to-growth flux variations, strain relaxation with 0.06% in-plane lattice mismatch was found in AlScN layers for the twenty period sample. By carefully tuning the Sc composition, pseudomorphic AlScN/GaN multilayer structures with more periods can be demonstrated in the future. The promising structural and surface/interface qualities indicate that lattice matched AlScN/GaN multilayer structures can serve as high quality templates and bottom reflectors for integration of active layers in vertical cavity emitters such as reported for AlInN.

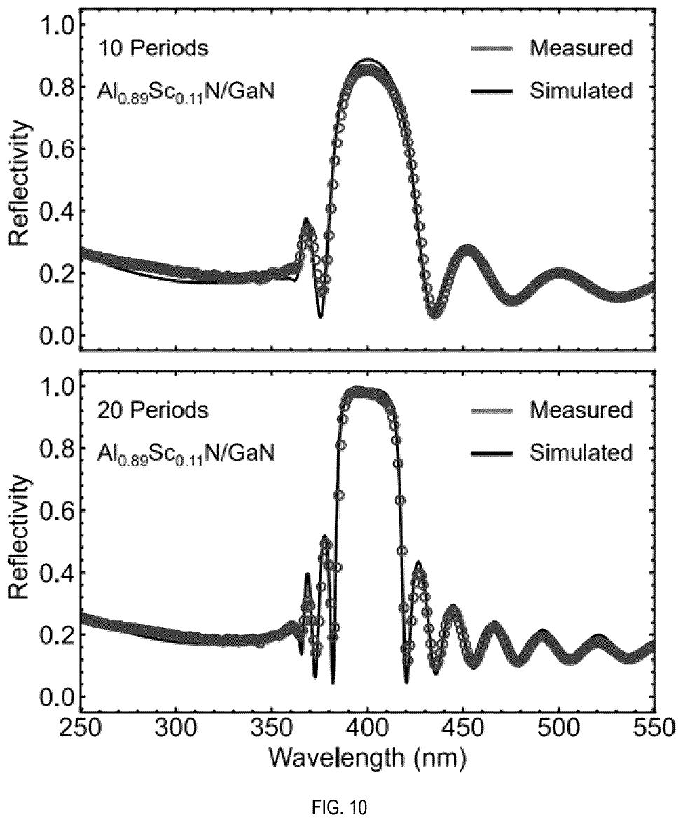

The normal incidence reflectivity spectra of the ten and twenty period DBRs near the photonic stop-band are shown in FIG. 10. FIG. 10 shows measured (spectrophotometry) and simulated (TMM) reflectivity spectra of a ten period (top) and twenty period (bottom) [symbol] distributed Bragg reflector with a measured peak reflectivity of 0.86 and 0.98, respectively, for a vacuum wavelength near 400 nm.

As predicted from the refractive index dispersion for GaN and [symbol] , the reflectivity spectra as simulated by the Transfer Matrix Method (TMM) match remarkably well with the experimental data for both the ten and twenty period DBRs, which are shown in FIG. 10. This is enabled by negligible optical interface scattering losses due to the sub-nm sharp interfaces and negligible optical losses as confirmed from ellipsometry, where the ordinary optical extinction coefficient, k, of [symbol] [symbol] layers was below the detection limit (k<<0.001) in the UV-A, visible and NIR regimes. The peak reflectivity was found to be 0.86 and 0.98 for the ten and twenty period DBRs, respectively, just slightly lower than the zero-loss predicted peak reflectivity values of 0.89 and 0.99. The full-width at half maximum of the photonic stop-bands are also in well agreement with the TMM simulated spectra, yielding values of 44 nm and 33 nm for the ten and twenty period DBRs, respectively.

It should be noted that below a wavelength of 365 nm, corresponding to the bandgap of GaN, the interference fringes disappear in the reflectivity spectra of FIG. 10 due to the onset of interband absorption. Therefore, AlScN/GaN DBRs are limited to a photon energies lower than the bandgap of GaN. However, the ultrawide bandgap of AlScN which is larger than 5 eV for scandium contents below 25% make AlScN/AlGaN multilayers suitable for DBRs operating at shorter wavelengths than those limited by the bandgap of GaN, into the UV-A, UV-B and UV-C regimes.

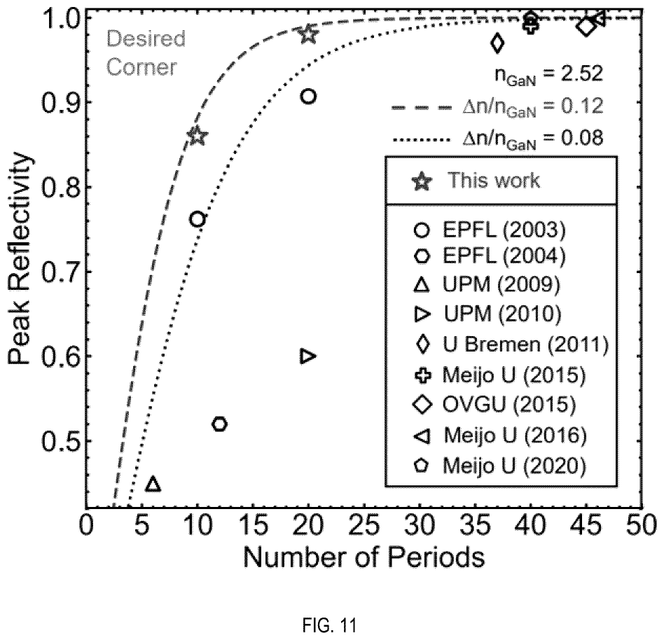

FIG. 11 is a benchmark plot of epitaxial lattice-matched nitride based distributed Bragg reflectors on GaN showing peak reflectivity vs. number of periods in the multilayer. Reports on AlInN/GaN multilayers are show in black and AlScN/GaN based DBRs demonstrated in this report are shown by violet stars. The theoretical zero-loss approximation for the reflectivity vs number of periods of GaN-based DBRs with index contrast Δn/n_{GaN} of 0.08 and 0.12 are shown in black and violet dashed curves, respectively. The ordinary refractive index of GaN, n_{GaN}, is set to 2.52, which was the measured value at λ=400 nm FIG. 5.

To put into perspective the advantages of using lattice-matched AlScN/GaN multilayer reflectors, we compare them with the extensively studied AlInN/GaN platform. Specifically, FIG. 4 shows a benchmark plot of epitaxial lattice-matched nitride based DBRs on GaN showing peak reflectivity vs number of periods in the multilayer.

Reports on AlInN/GaN multilayers ranging from 400-560 nm are shown in black and AlScN/GaN based DBRs demonstrated in this report are shown by violet stars. As predicted by the lower refractive index mismatch for the AlInN/GaN platform with an index contrast of Δn/n_{GaN}=0.08 (high estimate), AlScN/GaN outperforms AlInN/GaN due to its measured index contrast of Δn/n_{GaN}=0.12. This is in accordance with the theoretical zero-loss approximation for the reflectivity vs number of periods of GaN-based DBRs with Δn/n_{GaN} of 0.08 and 0.12 which are shown in black and violet dashed curves, respectively FIG. 11. The ordinary refractive index of GaN, n_{GaN}, is set to 2.52, which is the measured value at λ=400 nm FIG. 5. For example, for a target peak reflectance of 0.8, a total amount of 8 periods are required for AlScN/GaN, whereas it requires 12 periods for AlInN/GaN. For a peak reflectance of 0.999, one would need 29 periods of AlScN/GaN or 45 periods of AlInN/GaN, respectively. This emphasizes that the total required material thickness is reduced substantially for a mirror with a given target reflectivity for the AlScN/GaN platform.

As a final point of discussion, we emphasize one of the reasons for the large refractive index mismatch between AlScN and GaN to be the rapid increase of the in-plane lattice parameter of AlScN as the scandium incorporation is increased, allowing for lattice-matching to GaN at high Al compositions. This is ascribed partly to the anisocrystalline alloying of rock salt ScN with wurtzite AlN, which results in tilting of the metal-nitrogen tetrahedral bonds in the wurtzite phase, as well as the larger bond length of Sc-N as compared to Al-N. This prediction still holds true for alloying of the heavier transition metal nitrides YN or LaN with AlN. Here, the latter effect is even more significant due to the larger atomic radii of Y and La compared to Sc. These considerations indicate lattice-matching to GaN at even higher Al content in AlYN and AlLaN alloys, which could result in a larger refractive index mismatch than presented here. This encourages the further exploration of transition metal nitrides for integration with group III/N optoelectronics, in particular distributed Bragg reflectors.

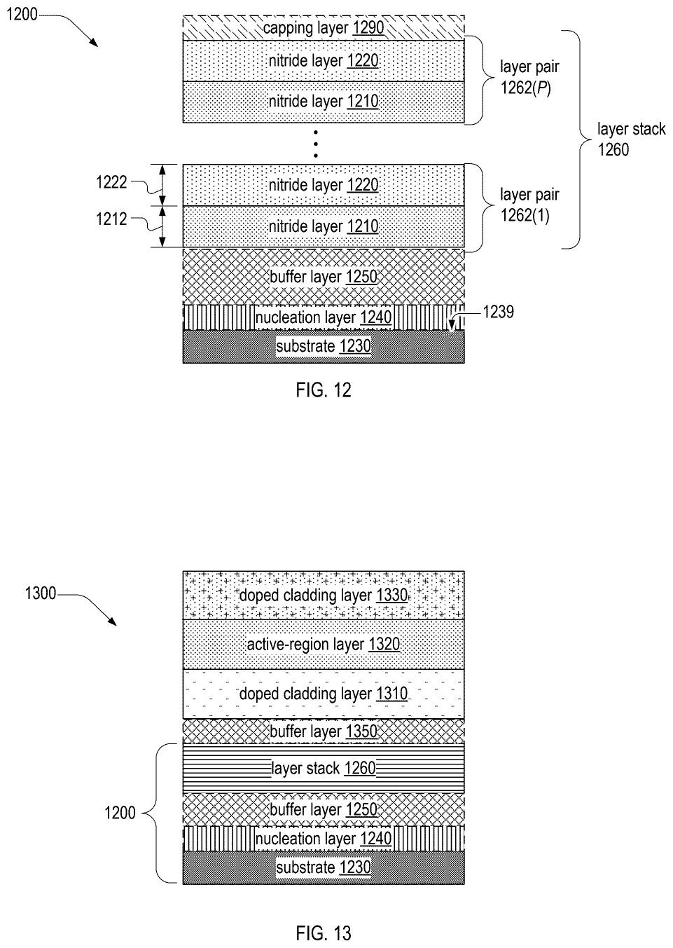

FIG. 12 is a cross-sectional schematic of a lattice-matched heterostructure 1200, hereinafter heterostructure 1200. Heterostructure 1200 includes a substrate 1230 and a layer stack 1260 on the substrate. Layer stack 1260 includes P layer pairs 1262 stacked thereon, where P is an integer greater than one. P may be less than or equal to one hundred. In embodiments P is less than or equal to at least one of forty, thirty, twenty, and ten. For example, P may be in one of the following ranges: between 1 and 10 inclusive, between 10 and 20 inclusive, between 20 and 30 inclusive, and between 30 and 40 inclusive. Multilayer structure 600, FIG. 6, is an example of heterostructure 1200.

Substrate 1230 has a top surface 1239; layer stack 1260 may be on top surface 1239. Layer pairs 1262 are stacked as a one-dimensional array and are arrayed in a direction perpendicular to a surface 1239. Heterostructure 1200 may include at least one of a nucleation layer 1240 and a buffer layer 1250 between layer stack 1260 and substrate 1230. Buffer layer 1250 may be a graded Al₁₋ₓMₓN layer or a graded Al_{1-y}Ga_{y}N layer or a graded Al_{1-x-y}¿ₓGa_{y}N layer to minimize the lattice-mismatch between substrate 1230 and layer stack 1260.

Each layer pair 1262 includes (i) a nitride layer 1210, which may include a metal and (ii) a nitride layer 1220, which may include at least one of aluminum and gallium. At least one of the nitride layers 1210 and 1220 may have a wurtzite crystal structure.

FIG. 12 illustrates, for a given layer pair 1262, nitride layers 1210 and 1220 being on the “bottom” and “top,” respectively, such that nitride layer 1210 of a layer pair 1262 is between substrate 1230 and nitride layer 1220 of the layer pair 1262. Without departing from the scope of the embodiments, each layer pair may be “flipped” such that nitride layers 1210 and 1220 of a layer pair 1262 are on the “top” and “bottom” respectively, such that nitride layer 1220 is between substrate 1230 and nitride layer 1210 of the layer pair 1262.

Nitride layers 1210 and 1220 have respective thicknesses 1212 and 1222, each of which may be between 0.1 nanometers and 100 nanometers. Example thickness ranges include between 0.1 nanometers and twenty nanometers and between one nanometer and five nanometers.

The material composition of either or both of nitride layer 1210 and 1220 may be expressed as Al_{1-y}Ga_{y}N. In embodiments, molar fraction y is between 0.85 and 1.0, inclusive. The material composition of either or both of nitride layers 1210 and 1220 may be expressed as Al₁₋ₓMₓN. In embodiments, M denotes a metallic element or a metalloid. For example, M may include one or more of a group-III element, a rare earth element, boron, and gallium. In embodiments, molar fraction x is between 0.01 and 0.18, inclusive. At least one of the following statements about M may apply to embodiments of heterostructure 1200:
1. M is scandium and x is between 0.07 and 0.18.
2. M is yttrium, and x is between 0.05 and 0.08.
3. M is a rare earth element of the lanthanide series, and x is between 0.01 and 0.045.
4. M is lanthanum, and x is between 0.02 and 0.045.
5. M including elements M1 and M2, such that the material composition of the first nitride layer is Al₁₋ₓM1ₓ₁M2ₓ₂N, where x=x₁+x₂.
6. M including a first group III element M1 and a second group III element M2, such that the material composition of the first nitride layer is Al₁₋ₓM1ₓ₁M2ₓ₂N, where x=x₁+x₂ and x is between 0.01 and 0.20.
7. M includes elements M1, M2, . . . , MP, where P is a positive integer greater than 2, such that the material composition of the first nitride layer is Al₁₋ₓ(M1ₓ₁M2ₓ₂ . . . MPₓ_{_{P}})N, where x=x₁+x₂+. . . +x_{P}. In embodiments, each of x₁, x₂, . . . , x_{P} is in a respective range R₁, R₂, . . . R_{P} each having a respective lower limit L₁, L₂, . . . L_{P} and a respective upper limit U₁, U₂, . . . U_{P}. In such embodiments, x is between the minimum of lower limits L₁, L₂, . . . L_{P} and the maximum of upper limits U₁, U₂, . . . U_{P}.

Each of nitride layer 1210 and nitride layers 1220 may include indium. In embodiments, a material compositions of nitride layers 1210 and 1220 are ¿ₓAl_{y}M_{z}N and ¿ₓAl_{y}Ga_{z}N, respectively. In such embodiments, at least one of (a) subscripts x, y, and z sum to one, (b) the quotient z/(x+y) is between 0.01 and 0.18 inclusive, and (c) x is between 0 and 0.8 inclusive, and y is between 0.40 and 1 inclusive. M includes one or more of a group-III element, a rare earth element, boron, and gallium.

Heterostructure 1200 may include a capping layer 1290 on layer stack 1260. Capping layer functions to protect heterostructure 1200 from oxidation damage and/or contamination. The material composition of capping layer 1290 may be gallium nitride. A thickness of capping layer 1290 may be greater than one nanometer and/or less than fifty nanometers.

In embodiments, the epitaxial growth of layers 1210 and 1220 results in each layer 1220 hosting electronic bound states in its conduction band. Layers 1210 function as quantum potential barriers, whereas layers 1220 function as quantum wells. The ground state and first excited state may be separated by an energy equal to the energy of the photon corresponding to a light wavelength in the infrared and red spectral regimes. The energy separation, and therefore the photon energy, may be tuned by varying the thickness of the quantum well and barrier thicknesses. In embodiments, a thickness of each of layers 1210 and 1220 is between 0.1 and 20 nanometers.

Embodiments of heterostructure 1200 may function as an intersubband photodetector. In such embodiments, the ground state may be populated by impurity and/or delta doping of one or both of nitride layers 1210 and 1220.

One or both of nitride layer 1210 and nitride layer 1220 may be formed via a digital growth process. For example, when layer 1210 has a material composition Al₁₋ₓMₓN, layer 1210 may be formed from by annealing a multilayer stack of layer pairs, where each layer pair includes an MN layer and a AlN layer. A ratio of the thickness of the MN layer to the AlN layer equals x. Similarly, when layer 1220 has a material composition Al_{1-y}Ga_{y}N, layer 1220 may be formed from by annealing a multilayer stack of layer pairs, where each layer pair includes an GaN layer and a AlN layer. A ratio of the thickness of the GaN layer to the AlN layer equals y. The annealing temperature may be between 600° C. and 900° C. and the annealing time may be between one minute and thirty minutes.

FIG. 13 is a cross-sectional schematic of a light emitting device 1300, which may be part of a resonant cavity LED (RCLED) or a vertical cavity surface-emitting laser (VCSEL). Device 1300 includes heterostructure 1200, a doped cladding layer 1310 on heterostructure 1200, an active-region layer 1320 on doped cladding layer 1310, and a doped cladding layer 1330 on active-region layer 1320. Doped cladding layers 1310 and 1330 may be viewed a “top” and “bottom” doped cladding layers, respectively. Device 1300 may include a buffer layer 1350 between layer stack 1260 and doped cladding layer 1310. Heterostructure 1200 may function as a distributed Bragg reflector (DBR) of device 1300.

Layer stack 1260 is between substrate 1230 and doped cladding layer 1310. Doped cladding layers 1310 and 1320 have opposite dopant types. For example, when doped cladding layer 1310 is n-doped, 1320 is p-doped; when doped cladding layer 1310 is p-doped, doped cladding layer 1320 is n-doped. Active-region layer 1320 has a center emission wavelength. In embodiments, each of nitride layers 1210 and 1220 are quarter-wave layers at this center emission wavelength. A material composition of each of doped cladding layer 1310 and active-region layer 1320 may include at least one of InGaN, AlGaN, AlScN, InAlN, InN, AlN, GaN, and ScN.

Due to lattice-matching and large refractive index offset between the Al_{1-y}Ga_{y}N and Al₁₋ₓMₓN multilayers, high-Q cavities and high structural integrity may be achieved for the light emitting device 1300.

Spontaneous emission in device 1300 may be achieved by optical, electron beam, or electrical pumping, or where stimulated emission is dominant by population inversion, also achieved by either optical, electron beam, or electrical pumping. Active-region layer 1320 may include additional p-type and n-type cladding layers to enable drift-diffusion injection of electron and holes. These cladding layers may be impurity-doped or compositionally graded, and their material composition may include one or more of the compounds listed above as candidate materials for cladding layers 1310 and 1320.

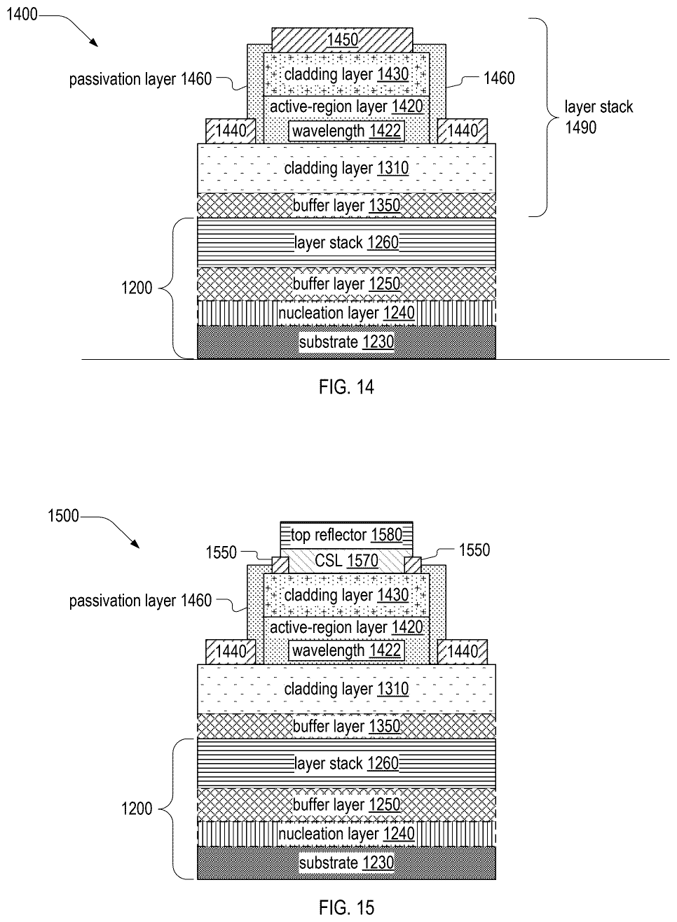

FIG. 14 is a cross-sectional schematic of a resonant cavity light-emitting diode (RCLED) 1400. RCLED 1400 is an example of device 1300 that includes an active-region layer 1420 and a doped cladding layer 1430, which are examples of active-region layer 1320 and doped cladding layer 1330, respectively.

RCLED 1400 also includes an electrical contact 1450 and at least one conductive contact 1440. Each electrical contact 1440 forms a metal-semiconductor junction with cladding layer 1310. Electrical contact 1450 forms a metal-semiconductor junction with cladding layer 1430. The regions of FIG. 14 labeled as electrical contact 1440 may represent either distinct electrical contacts 1440 or different regions of a single electrical contact 1440. For example, electrical contact 1440 may at least partially surround active-region layer 1420. Electrical contact 1450 may function as a top reflector, may be at least partially transparent, and may include an aperture that exposes part of doped cladding layer 1430.

RCLED 1400 may also include a passivation layer 1460, which is on a top surface and/or a side surface of at least one of active-region layer 1420, doped cladding layer 1430, each electrical contact 1440, and electrical contact 1450. FIG. 14 denotes a layer stack 1490, which includes doped cladding layer 1310, active-region layer 1420, doped cladding layer 1430, electrical contact 1450, and, in embodiments, buffer layer 1350.

In RCLED 1400, layer stack 1260 functions as a high-reflectivity distributed Bragg reflector, the bottom mirror of RCLED 1400.

The lattice-matching of layers 1210 and 1220 results in high structural perfection, enabling layer stack 1260 to simultaneously act as a substrate for epitaxial growth of layer stack 1490, where low structural deformation for the pristine bottom reflectors enable high internal quantum efficiency active-region layer 1420 and, in embodiments, an optical cavity that includes layer stacks 1260 and 1490. Furthermore, large refractive index mismatch at lattice-matched condition limits total periods and therefore material thickness required in the multilayer structure.

Active-region layer 1420 has an emission spectrum with a center wavelength 1422. In embodiments, a thickness of each layer of layer stack 1260 is a quarter of center wavelength 1422. In embodiments, each of nitride layer 1210 and nitride layers 1220 are quarter-wave layers at center wavelength 1422. In such embodiments, each of the following is equal to one-quarter of center wavelength 1422: (i) a product of a first geometric thickness and a first refractive index of nitride layer 1210 and (ii) a product of a second geometric thickness and a second refractive index of nitride layer 1220.

FIG. 15 is a cross-sectional schematic of a vertical cavity surface-emitting laser (VCSEL) 1500. VCSEL 1500 is an example of device 1300 that includes active-region layer 1420 and doped cladding layer 1430, at least one electrical contact 1440, and passivation layer 1460, introduced in FIG. 14. VCSEL 1500 also includes, on doped cladding layer 1430, at least one electrical contact 1550, a transparent current-spreading layer (CSL) 1570, and a top reflector 1580. CSL 1570 is between doped cladding layer 1430 and CSL 1570.

Electrical contact 1550 is an example of electrical contact 1450. The regions of FIG. 15 labeled as electrical contact 1550 may represent either distinct electrical contacts 1550 or different regions of a single electrical contact 1550. For example, electrical contact 1550 may form an aperture on or be U-shaped, such that the cross-sectional view of RCLED 1400 in FIG. 14 includes two regions of electrical contact 1450.

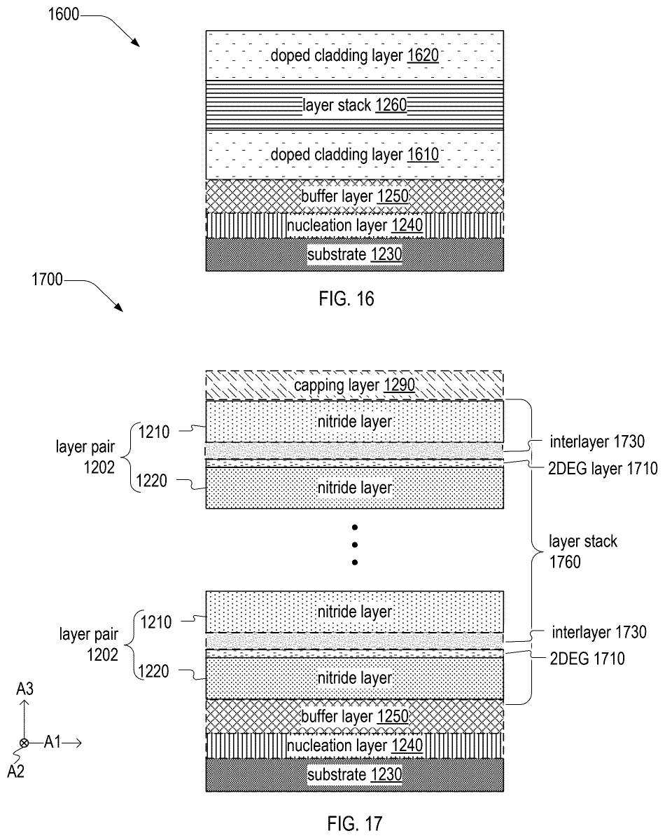

FIG. 16 is a cross-sectional schematic of a quantum cascade emitter 1600, which includes heterostructure 1200, a doped cladding layer 1610, and a doped cladding layer 1620. Doped cladding layer 1610 has a first dopant type and is between layer stack 1260 and substrate 1230 of heterostructure 1200. Doped cladding layer 1620 has a second dopant type and is on layer stack 1260, such that layer stack 1260 is between doped cladding layer 1610 and doped cladding layer 1620. The second dopant type may be the same or different from the first dopant type. In embodiments, each of layers 1610 and 1620 is n-type doped, or each of layers 1610 and 1620 is p-type doped. In embodiments, one of layers 1610 and 1620 is n-type doped and the other of layers 1610 and 1620 is p-type doped.

In quantum cascade emitter 1600, layer stack 1260 is embedded between layers 1610 and 1620, which allows for population of the excited state quantum well levels by electrical injection. Lattice-matching of 1210 and 1220 enables high interface quality and crystallinity and therefore high quantum efficiency of quantum cascade emitter 1600 by reducing point defect formation and dislocations which act as photon/electron absorbers/scatterers.

FIG. 17 is a cross-sectional schematic of a heterostructure 1700. FIG. 17 includes orthogonal axes A1, A2, and A3. The cross-section of FIG. 17 is in the A1-A3 plane. Heterostructure 1700 is an example of heterostructure 1200 introduced in FIG. 12 and includes a layer stack 1760, which is an example of layer stack 1260. Layer stack 1760 includes a respective two-dimensional electron gas layer 1710 (hereinafter 2DEG layer 1710) between nitride layers 1210 and 1220 of each layer pair 1262.

Heterostructure 1700 may also include a respective interlayer 1730 between nitride layers 1210 and 1220 of each layer pair 1262. The material composition of respective interlayer 1730 may include aluminum nitride and/or Al_{1-z}Ga_{z}N. When the material composition of nitride layer 1220 is or includes Al_{1-y}Ga_{y}N, z is less than y.

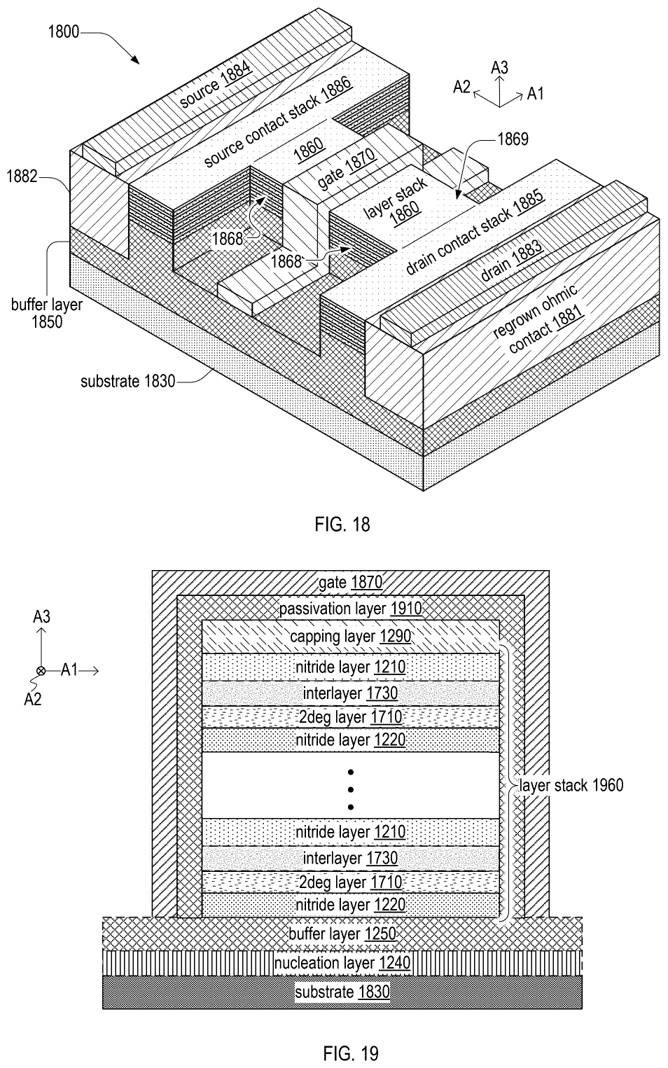

FIG. 18 is a plan view of a multichannel field-effect transistor 1800, hereinafter FET 1800. FET 1800 includes a substrate 1830, a layer stack 1860 on substrate 1830, and a gate 1870. Substrate 1830 and layer stack 1860 are respective examples of substrate 1230 and layer stack 1760. FIG. 17 represents a cross-sectional view of layer stack 1860 in the A1-A3 plane.

FET 1800 may include at least one of a buffer layer 1850, regrown ohmic contacts 1881 and 1882, a drain 1883, a source 1884, a source contact stack 1884, and a drain contact stack 1885. Buffer layer 1850 is between substrate 1830 and layer stack 1860 and is an example of buffer layer 1250. Contact stacks 1885 and 1886 are wider along axis A1 than layer stack 1860, as shown in FIG. 18. In embodiments, the stack structure (layer count, materials, thicknesses) of each of contacts stacks 1885 and 1886 may be the same as, or different from, that of layer stack 1860.

Gate 1870 covers part of a side surface 1868 and part of a top surface 1869 of layer stack 1860. FIG. 17 includes orthogonal axes A1, A2, and A3 introduced in FIG. 17. Surfaces 1868 and 1869 which may be parallel to A2-A3 plane and the A1-A3 plane, respectively. FET 1800 may include at least one of nucleation layer 1240 and buffer layer 1250 between substrate 1830 and layer stack 1760.

FIG. 19 is a cross-sectional view of a multichannel field-effect transistor 1900, hereinafter FET 1900, which is an example of FET 1800.

FET 1900 includes substrate 1830, layer stack 1960, a passivation layer 1920, and gate 1870. Layer stack 1960 is an example of layer stack 1860.

FET 1900 may also include at least one of buffer layer 1250 and nucleation layer 1240. In the cross-sectional plane of FIG. 19, which is parallel to the A1-A3 plane, passivation layer 1910 covers a top surface and side surface of layer stack 1960.

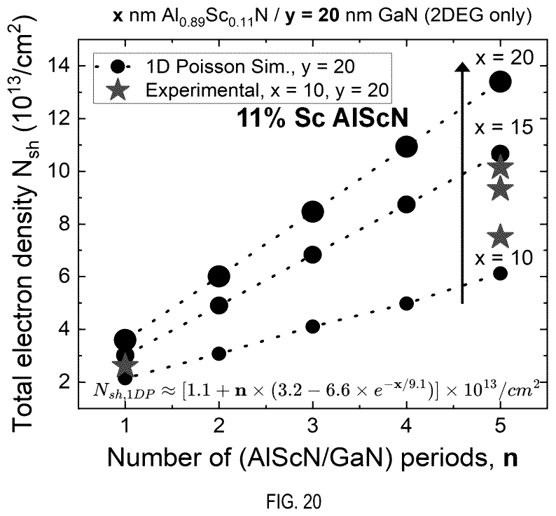

FIG. 20 is a plot of total electron density in 2DEG layer 1710 as a function of number of periods P of respective embodiments of heterostructure 1700. In this embodiment, substrate 1230 is formed of 4H SiC, nucleation layer 1240 is a 100-nm thick aluminum nitride layer, buffer layer 1250 is a 600-nm thick GaN layer, each nitride layer 1210 is a 10-nm thick Al_{0.89}Sc_{0.11}N layer, and each nitride layer 1220 is a GaN layer having a thickness of approximately 20 nm. The total charge and a number of 2DEGs scales with a number of AlScN/GaN superlattice periods.

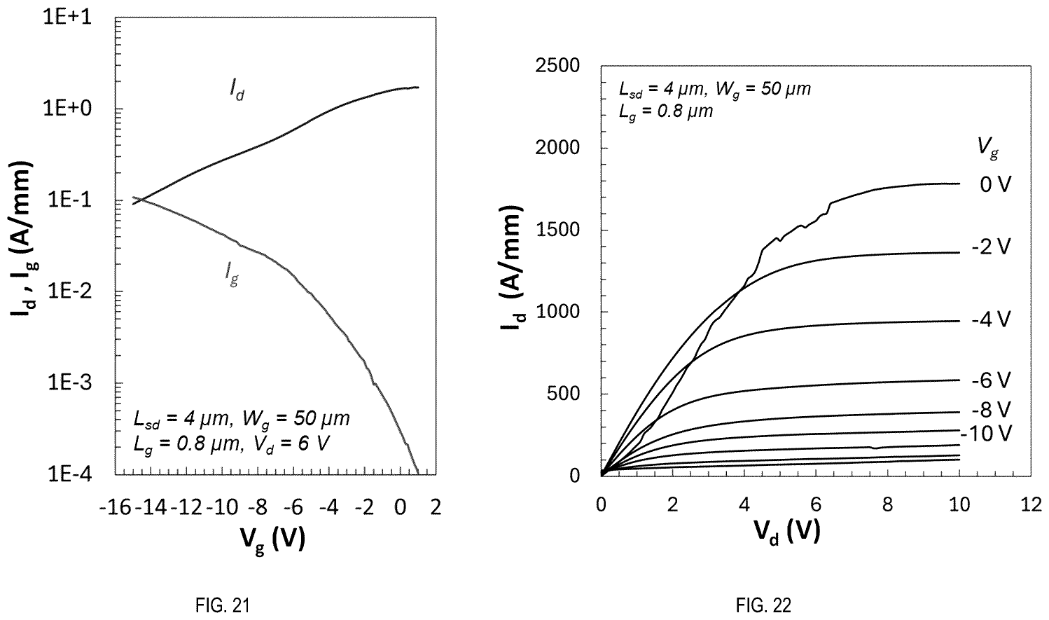

FIG. 21 and FIG. 22 are plots of voltage-current characteristics of an embodiment of FET 1800 that has the embodiment of heterostructure 1700 associated with FIG. 20, where the number of periods P is five each nitride layer 1210 is a 20-nm thick GaN layer, each nitride layer 1220 is a 10-nm thick AlScN layer, and capping layer 1290 is a 5-nm thick GaN layer. FIG. 21 is a plot of drain current I_{d} and gate current I_{g} as a function of threshold voltage V_{g}. FIG. 22 is a plot of drain current I_{d} as a function of drain-source voltage Vd for different values of threshold voltage V_{g}.

Features described above, as well as those claimed below, may be combined in various ways without departing from the scope hereof. The following enumerated examples illustrate some possible, non-limiting combinations.

### Combinations of Features

Embodiment 1. A heterostructure comprising: a substrate; and a layer stack of layer pairs on the substrate, each of the layer pairs having (i) a first nitride layer that includes a metal and (ii) a second nitride layer that includes aluminum and gallium.

Embodiment 2. The heterostructure of embodiment 1, a material composition of the first nitride layer being Al₁₋ₓMₓN, where x is between 0.01 and 0.18, inclusive, and M includes one or more of a group-III element, a rare earth element, boron, and gallium; and a material composition of the second nitride layer being Al_{1-y}Ga_{y}N, where y is between 0.85 and 1.0, inclusive.

Embodiment 3. The heterostructure of either one of embodiments 1 or 2, the layer stack including at most one hundred layer pairs.

Embodiment 4. The heterostructure of either one of embodiments 2 or 3, M being scandium and x being between 0.07 and 0.18.

Embodiment 5. The heterostructure of any one of embodiments 2-4, M being yttrium, and x being between 0.05 and 0.08

Embodiment 6. The heterostructure of any one of embodiments 2-5, M being a rare earth element of the lanthanide series, and x being between 0.01 and 0.045.

Embodiment 7. The heterostructure of embodiment 6, M being lanthanum, and x being between 0.02 and 0.045.

Embodiment 8. The heterostructure of any one of embodiments 2-7, M including elements M1 and M2, such that the material composition of the first nitride layer is Al₁₋ₓM1ₓ_{₁}M2ₓ_{₂}N, where x=x₁+x₂.

Embodiment 9. The heterostructure of any one of embodiments 2-8, M including a first group III element M1 and a second group III element M2, such that the material composition of the first nitride layer is Al₁₋ₓM1ₓ_{₁}M2ₓ_{₂}N, where x=x₁+x₂ and x is between 0.01 and 0.20.

Embodiment 10. The heterostructure of any one of embodiments 2-9, M including elements M1, M2, . . . , M_{P}, where P is a positive integer greater than 2, such that the material composition of the first nitride layer is Al₁₋ₓ(M1ₓ_{₁}M2ₓ_{₂} . . . MPₓ_{_{P}})N, where x=x₁+x₂+. . . +x_{P}.

Embodiment 11. The heterostructure of embodiment 10, each of x₁, x₂, . . . , x_{P} being in a respective range R₁, R₂, . . . R_{P} each having a respective lower limit L₁, L₂, . . . L_{P} and a respective upper limit U₁, U₂, . . . U_{P}, and x is between the minimum of lower limits L₁, L₂, . . . L_{P} and the maximum of upper limits U₁, U₂, . . . U_{P}.

Embodiment 12. The heterostructure of any one of embodiments 1-11, a material composition of the first nitride layer being ¿ₓAl_{y}M_{z}N; a material composition of the second nitride layer being ¿ₓAl_{y}Ga_{z}N; wherein x, y, and z sum to one, the quotient z/(x+y) is between 0.01 and 0.18 inclusive, x is between 0 and 0.8 inclusive, and y is between 0.40 and 1 inclusive; and M includes one or more of a group-III element, a rare earth element, boron, and gallium.

Embodiment 13. The heterostructure of any one of embodiments 1-11, a thickness of each of the first nitride layer and the second nitride layer being between 0.1 nanometers and 100 nanometers.

Embodiment 14. The heterostructure of any one of embodiments 1-11, a thickness of each of the first nitride layer and the second nitride layer being between one nanometer and five nanometers.

Embodiment 15. A light emitting device comprising: the heterostructure of any one of embodiments 1-14, a first doped cladding layer on the heterostructure and having a first dopant type; an active-region on the first doped cladding layer and having a center emission wavelength; and a second doped cladding layer on the active-region and having a second dopant type that is opposite the first dopant type; wherein each of the first nitride layer and the second nitride layer of the heterostructure are quarter-wave layers at the center emission wavelength.

Embodiment 16. The light emitting device of embodiment 15, further comprising a top reflector on the second doped cladding layer.

Embodiment 17. The light emitting device of embodiment 16,further comprising a transparent current-spreading layer between the top reflector and the second doped cladding layer.

Embodiment 18. The light emitting device of any one of embodiments 15-17: a product of a first geometric thickness and a first refractive index of the first nitride layer, at the center emission wavelength, being equal to one-quarter of the center emission wavelength; and a product of a second geometric thickness and a second refractive index of the second nitride layer, at the center emission wavelength, being equal to one-quarter of the center emission wavelength.

Embodiment 19. The light emitting device of any one of embodiments 15-18, a material composition of each of the first doped cladding layer and the second doped cladding layer including at least one of InGaN, AlGaN, AlScN, InAlN, InN, AlN, GaN, and ScN.

Embodiment 20. A quantum cascade emitter comprising: the heterostructure of any one of embodiments 1-14; a bottom doped cladding layer located between the layer stack and the substrate and having a first dopant type; and a top doped cladding layer located on the layer stack and having the first dopant type.

Embodiment 21. A field-effect transistor comprising: the heterostructure of of any one of embodiments 1-14, wherein the layer stack further includes a respective two-dimensional electron gas between the first nitride layer and the second nitride layer of each layer pair.

Changes may be made in the above methods and systems without departing from the scope of the present embodiments. It should thus be noted that the matter contained in the above description or shown in the accompanying drawings should be interpreted as illustrative and not in a limiting sense. Herein, and unless otherwise indicated the phrase “in embodiments” is equivalent to the phrase “in certain embodiments,” and does not refer to all embodiments.

Regarding instances of the terms “and/or” and “at least one of,” for example, in the cases of “A and/or B,” “at least one of A and B,” and “at least one of A or B,” such phrasing encompasses the selection of (i) A only, or (ii) B only, or (iii) both A and B. In the cases of “A, B, and/or C, ” “at least one of A, B, and C,” and “at least one of A, B, or C,” such phrasing encompasses the selection of (i) A only, or (ii) B only, or (iii) C only, or (iv) A and B only, or (v) A and C only, or (vi) B and C only, or (vii) each of A and B and C. This may be extended for as many items as are listed.

The following claims are intended to cover all generic and specific features described herein, as well as all statements of the scope of the present method and system, which, as a matter of language, might be said to fall therebetween.

We claim:

1. A heterostructure comprising:
a substrate; and
a layer stack of layer pairs on the substrate, each of the layer pairs having (i) a first nitride layer that includes a metal and (ii) a second nitride layer that includes aluminum and gallium.

2. The heterostructure of claim 1,
a material composition of the first nitride layer being Al₁₋ₓMₓN, where x is between 0.01 and 0.18, inclusive, and M includes one or more of a group-III element, a rare earth element, boron, and gallium; and
a material composition of the second nitride layer being Al_{1-y}Ga_{y}N, where y is between 0.85 and 1.0, inclusive.

3. The heterostructure of claim 1, the layer stack including at most one hundred layer pairs.

4. The heterostructure of claim 2, M being scandium and x being between 0.07 and 0.18.

5. The heterostructure of claim 2, M being yttrium, and x being between 0.05 and 0.08.

6. The heterostructure of claim 2, M being a rare earth element of the lanthanide series, and x being between 0.01 and 0.045.

7. The heterostructure of claim 6, M being lanthanum, and x being between 0.02 and 0.045.

8. The heterostructure of claim 2, M including elements M1 and M2 , such that the material composition of the first nitride layer is Al₁₋ₓM1ₓ_{₁}M2ₓ_{₂} N, where x=x₁+x₂.

9. The heterostructure of claim 2, M including a first group III element M1 and a second group III element M2 , such that the material composition of the first nitride layer is Al₁₋ₓM1ₓ_{₁} M2ₓ_{₂} N, where x=x₁+x₂ and x is between 0.01 and 0.20.

10. The heterostructure of claim 2, M including elements M₁, M2 , . . . , MP, where P is a positive integer greater than 2, such that the material composition of the first nitride layer is Al₁₋ₓ(M1ₓ_{₁} M2ₓ_{₂} . . . MPₓ_{_{P}})N, where x=x₁+x₂+. . . +x_{P}.

11. The heterostructure of claim 10, each of x₁, x₂, . . . , x_{P} being in a respective range R₁, R₂, . . . R_{P} each having a respective lower limit L₁, L₂, . . . L_{P} and a respective upper limit U₁, U₂, . . . U_{P}, and x is between the minimum of lower limits L₁, L₂, . . . L_{P} and the maximum of upper limits U₁, U₂, . . . U_{P}.

12. The heterostructure of claim 1,
a material composition of the first nitride layer being ¿ₓAl_{y}M_{z}N;
a material composition of the second nitride layer being ¿ₓAl_{y}Ga_{z}N; wherein x, y, and z sum to one, the quotient z/(x+y) is between 0.01 and 0.18 inclusive, x is between 0 and 0.8 inclusive, and y is between 0.40 and 1 inclusive; and
M includes one or more of a group-III element, a rare earth element, boron, and gallium.

13. The heterostructure of claim 1, a thickness of each of the first nitride layer and the second nitride layer being between 0.1 nanometers and 100 nanometers.

14. The heterostructure of claim 1, a thickness of each of the first nitride layer and the second nitride layer being between one nanometer and five nanometers.

15. A light emitting device comprising:
the heterostructure of claim 1;
a first doped cladding layer on the heterostructure and having a first dopant type;
an active-region on the first doped cladding layer and having a center emission wavelength; and
a second doped cladding layer on the active-region and having a second dopant type that is opposite the first dopant type;
wherein each of the first nitride layer and the second nitride layer of the heterostructure are quarter-wave layers at the center emission wavelength.

16. The light emitting device of claim 15, further comprising a top reflector on the second doped cladding layer.

17. The light emitting device of claim 16, further comprising a transparent current-spreading layer between the top reflector and the second doped cladding layer.

18. The light emitting device of claim 15:
a product of a first geometric thickness and a first refractive index of the first nitride layer, at the center emission wavelength, being equal to one-quarter of the center emission wavelength; and
a product of a second geometric thickness and a second refractive index of the second nitride layer, at the center emission wavelength, being equal to one-quarter of the center emission wavelength.

19. The light emitting device of claim 15, a material composition of each of the first doped cladding layer and the second doped cladding layer including at least one of InGaN, AlGaN, AlScN, InAlN, InN, AlN, GaN, and ScN.

20. A quantum cascade emitter comprising:
the heterostructure of claim 1;
a bottom doped cladding layer located between the layer stack and the substrate and having a first dopant type; and
a top doped cladding layer located on the layer stack and having the first dopant type.

21. A field-effect transistor comprising:
the heterostructure of claim 1, wherein the layer stack further includes a respective two-dimensional electron gas between the first nitride layer and the second nitride layer of each layer pair.
